(19) United States
(12) Patent Application Publication
(10) Pub. No.: US 2019/0369688 A1
(43) Pub. Date: Dec. 5, 2019

(54) SEMICONDUCTOR DEVICE

(71) Applicant: RENESAS ELECTRONICS CORPORATION, Tokyo (JP)

(72) Inventors: Akira TANABE, Tokyo (JP); Kazuya UEJIMA, Tokyo (JP)

(21) Appl. No.: 16/406,814

(22) Filed: May 8, 2019

(30) Foreign Application Priority Data
May 30, 2018 (JP) 2018-103764

(51) Int. Cl. G06F 1/26; G01R 19/00; G05F 1/46

(52) U.S. Cl. CPC G06F 1/26; G05F 1/46; G01R 19/0038

(57) ABSTRACT

A semiconductor device can stably execute a start-up operation in a simple manner. The semiconductor device is driven by a power supply voltage generated by a power generation device. the semiconductor device includes a load circuit for receiving the power supply voltage from a power supply node, a switch provided between the power supply node and the load circuit, a first capacitor connected to the power supply node in parallel with the switch, and a switch control circuit for controlling the switch based on a voltage level of the power supply node.

### CROSS-REFERENCE TO RELATED APPLICATIONS

The disclosure of Japanese Patent Application No. 2018-103764 filed on May 30, 2018 including the specification, drawings and abstract is incorporated herein by reference in its entirety.

### BACKGROUND

The present disclosure relates to a semiconductor device driven by a power supply voltage generated by a power generation device.

Various types of power generation devices have been proposed for a long time, such as solar power generation, thermal power generation, and self-winding power generation in which power is generated by taking in kinetic energy by swinging the device itself.

In Japanese Patent No. 5458692, there is disclosed an electronic device that is driven by using the power generation device.

### SUMMARY

However, Japanese Patent No. 5458692 proposes a configuration having a function of distributing the generated power of the solar cell to two types of charging elements. On the other hand, a large power is required at the time of starting the electronic device. In Japanese Patent No. 5458692, that countermeasure is not proposed.

The present disclosure has been made to solve the above problem. In an aspect, an object of this invention is to provide a semiconductor device capable of stably executing a start-up operation in a simple manner.

Other objects and novel features will become apparent from the description and the accompanying drawings.

A semiconductor device according to an aspect of the present disclosure is driven by a power supply voltage generated by a power generation device. The semiconductor device includes a load circuit receiving the power supply voltage from a power supply node, a switch provided between the power supply node and the load circuit, a first capacitor coupled to the power supply node in parallel with the switch, and a switch control circuit controlling the switch based on a voltage level of the power supply node.

According to one embodiment, the semiconductor device of the present disclosure can stably execute the start-up operation in a simple manner.

### BRIEF DESCRIPTION OF THE DRAWINGS

FIG. 1 is a diagram for explaining an outline of a solar system 1 according to a first embodiment;

FIG. 2 is a diagram for explaining an example of a start-up sequence of a microcomputer 20 according to the first embodiment;

FIG. 3 is a diagram for explaining an outline of a solar system 1# as a comparative example.

FIGS. 4A, 4B, 4C and 4D are diagrams for explaining an operation example of the solar system 1 # as the comparative example.

FIG. 5 is a diagram for explaining a configuration of a voltage detection circuit 12 according to the first embodiment;

FIGS. 6A and 6B are diagrams for explaining an operation example of the solar system 1 according to the first embodiment;

FIGS. 7A and 7B are diagrams for explaining an operation example of the solar system 1 based on the first embodiment;

FIGS. 8A and 8B are the other diagram for explaining an operation example of the solar system 1# as the comparison example;

FIG. 9 is diagrams for explaining an outline of a solar system 1P according to a second embodiment;

FIGS. 10A and 10B are diagrams for explaining an operation example of the solar system 1P according to the second embodiment;

FIG. 11 is a flow chart for explaining an operation of the solar system 1P according to the second embodiment;

FIG. 12 is a diagram for explaining an outline of a solar system 1Q according to a third embodiment;

FIG. 13 is a diagram for explaining a configuration of a MOSFET formed on an SOI (Silicon on Insulator) wafer;

FIGS. 14A and 14B are diagrams for explaining a relation between a back bias voltage VSUB and a leakage current Ioff in an off state of a MOS transistor.

FIGS. 15A and 15B are diagrams for explaining a relation between a threshold voltage and a back bias voltage.

FIG. 16A and 16B are diagrams for explaining an operation example of the solar system 1Q according to the third embodiment;

### DETAILED DESCRIPTION

Embodiments of the present invention will be described in detail with reference to the accompanying drawings. In the drawings, the same or like components are designated by the same reference numerals. Thus, the detailed description thereof will not be repeated.

### First Embodiment

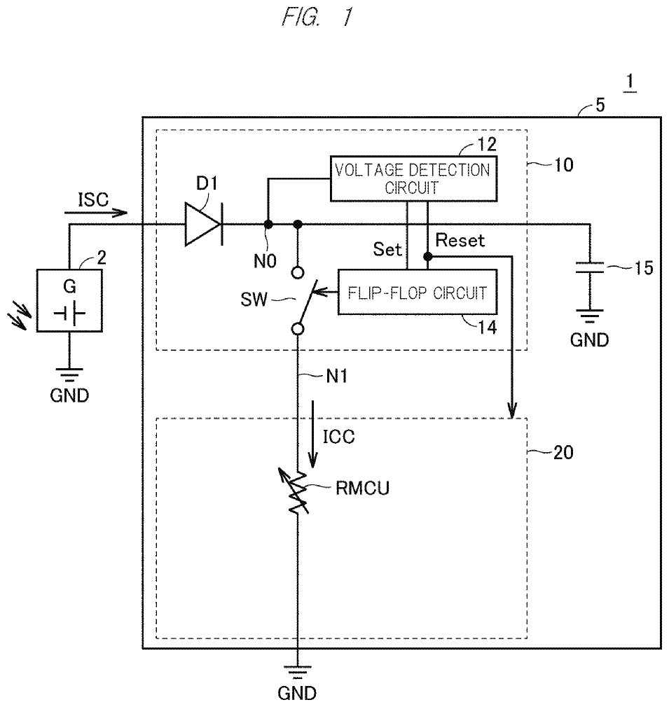

FIG. 1 is a diagram for explaining an outline of a solar system 1 according to a first embodiment.

Referring to FIG. 1, the solar system 1 includes a solar cell 2 which is a power generation device, and a control device 5 which receives a power supply voltage generated by the solar cell 2 and thereby drives.

As an example, the control device 5 is a semiconductor device. The control device 5 includes a power supply module 10 and a microcomputer 20.

In this embodiment, a resistive element RMCU is shown as a load of the microcomputer 20 (a load circuit). The power supply module 10 includes a backflow prevention diode D1, a capacitor 15, a switch SW, a voltage detection circuit 12, and a flip-flop circuit 14.

The backflow prevention diode D1 is provided between the solar cell 2 and a node N0. The voltage detection circuit 12 compares a voltage of the node N0 with a reference voltage, and outputs a comparison result to the flip-flop circuit 14.

The node N0 is coupled to the capacitor 15. Therefore, the power supply voltage generated by the solar cell 2 can be applied to the capacitor 15. In this example, a configuration in which the capacitor 15 is provided will be described, but the present invention is not limited to the capacitor, and a secondary battery may be used. In addition, the configuration is not limited to the configuration built in the control device 5, and a configuration may be such that the capacitor 15 is coupled at an outside of the control device 5.

The switch SW is coupled to the node N0 in parallel with the capacitor 15 and is provided between the node N0 and an internal node N1. The switch SW is controlled based on an output of the flip-flop circuit 14.

The voltage detection circuit 12 outputs a control signal Set to the flip-flop circuit 14. The voltage detection circuit 12 outputs a control signal Reset to the flip-flop circuit 14. The flip-flop circuit 14 sets data to 1 based on an input of the control signal Set. Based on this, the flip-flop circuit 14 turns on the switch SW. The voltage detection circuit 12 and the flip-flop circuit 14 comprise a switch control circuit for controlling the switch SW.

Further, the voltage detection circuit 12 outputs the control signal Reset as a reset signal of the microcomputer 20. On the other hand, the flip-flop circuit 14 resets data to 0 based on an input of the control signal Reset. Based on this, the switch SW is set to be non-conductive.

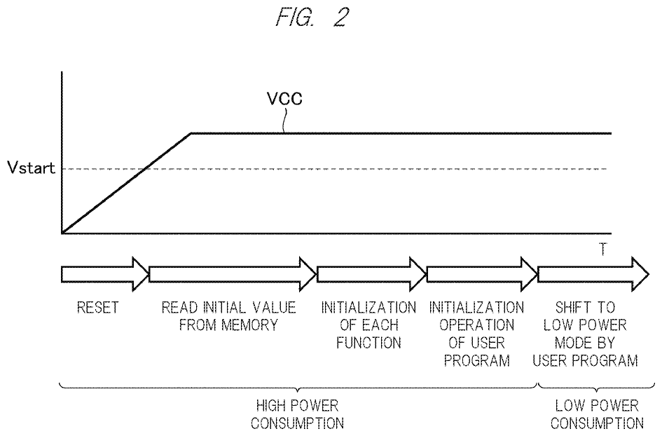

FIG. 2 is a diagram for explaining an example of a start-up sequence of the microcomputer 20 according to the first embodiment. Referring to FIG. 2, for example, when the power supply voltage VCC becomes equal to or higher than a reference voltage Vstart as the voltage level of the power supply voltage VCC rises, an initial value is read from a memory. Next, each function is initialized. Then, an initialization operation of a user program is executed. Then, the microcomputer 20 is shifted to a low power mode by the user program. A current consumption is large until the microcomputer 20 shifts to the low power mode according to the user program. On the other hand, in the low power mode of the microcomputer 20, the current consumption is small. That is, a power consumption of the microcomputer 20 at a time of start-up is larger than a power consumption of the microcomputer 20 at a time of steady state. In addition, the power consumption of the microcomputer 20 at the time of steady state is smaller than a power generation amount generated by the solar cell 2.

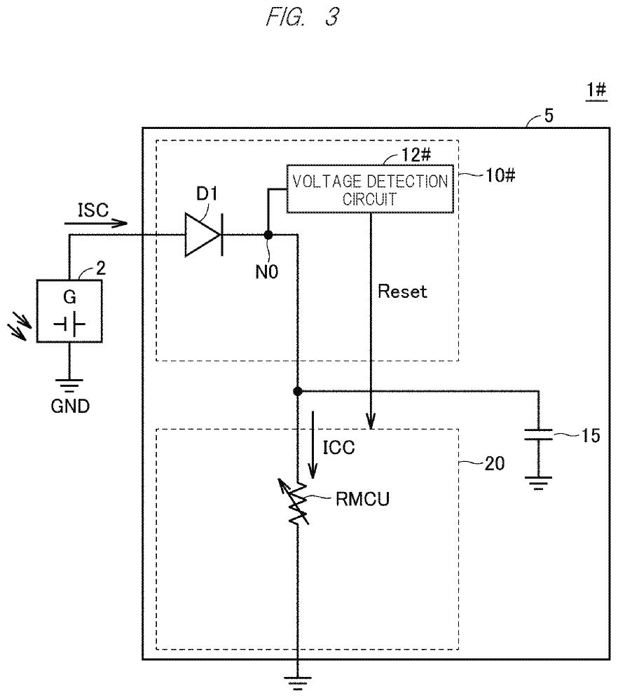

FIG. 3 is a diagram for explaining an outline of a solar system 1# as a comparative example. Referring to FIG. 3, the solar system 1# differs from the solar system 1 in a configuration of the power supply module. A power supply module 10# of the solar system 1# is provided with only a voltage detection circuit 12# and the backflow prevention diode D1, and is not provided with the switch SW, the flip-flop circuit 14, the capacitor 15, and the like.

In this configuration, the voltage detection circuit 12# detects a drop of a voltage of the node N0 and outputs a control signal Reset. Specifically, the voltage detection circuit 12# detects whether or not the voltage of the node N0 is equal to or less than a reference voltage Vreset, and outputs the control signal Reset to the microcomputer 20 when it is judged that the voltage is equal to or less than the reference voltage Vreset.

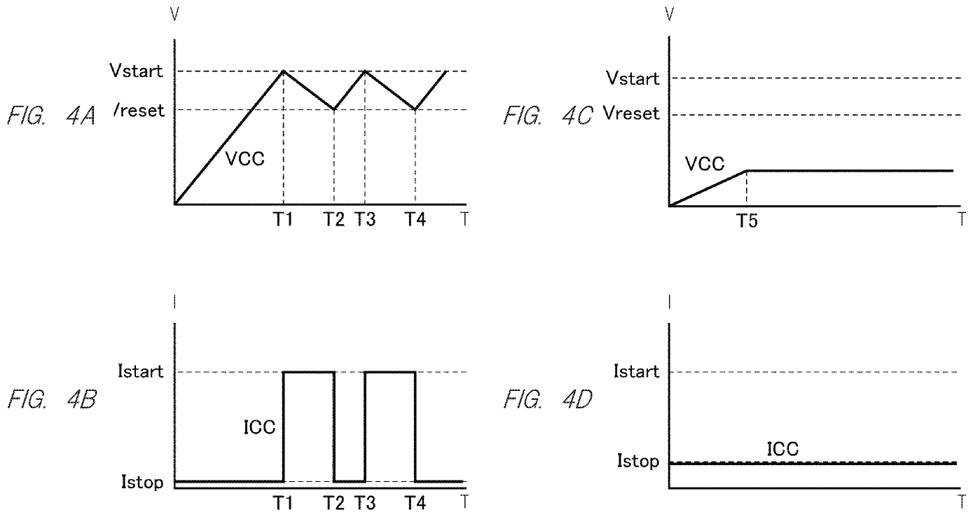

FIGS. 4A, 4B, 4C and 4D are diagrams for explaining an operation example of the solar system 1# as the comparative example. FIGS. 4A and 4B show examples in which the power supply voltage is unstable.

As shown in FIG. 4A, when the voltage reaches the reference voltage Vstart at the time T1, a start-up sequence operation of the microcomputer 20 is started. On the other hand, at time T2, the voltage drops to the reference voltage Vreset. Accordingly, the voltage detection circuit 12# outputs the control signal Reset due to the voltage drop. As a result, the start-up sequence operation of the microcomputer 20 is stopped.

When the voltage reaches the reference voltage Vstart at the time T3, the start-up sequence operation of the microcomputer 20 is started. On the other hand, at time T4, the voltage drops to the reference voltage Vreset. Accordingly, the voltage detection circuit 12# outputs the control signal Reset due to the voltage drop. As a result, the start-up sequence operation of the microcomputer 20 is stopped.

FIG. 4B shows a current ICC flowing based on the start-up sequence operation. Therefore, there is a possibility that the start-up sequence operation of the microcomputer 20 is not completed by repeating the operation.

FIGS. 4C and 4D show examples in which a load is heavy. As shown in FIG. 4C, the voltage does not reach the reference voltage Vstart at the time T5. Therefore, the start sequence operation is not executed.

As shown in FIG. 4D, the current ICC also maintains an initial state. Therefore, even when the load of the microcomputer 20 is heavy, there is a possibility that the start-up sequence operation is not executed.

FIG. 5 is a diagram for explaining a configuration of the voltage detection circuit 12 according to the first embodiment. Referring to FIG. 5, the voltage detection circuit 12 includes a reference voltage generation circuit 120 and comparators 122 and 124.

The reference voltage generation circuit 120 generates the reference voltages Vstart and Vreset. The comparator 122 compares the voltage of the node N0 with the reference voltage Vstart, and outputs a signal based on the result of the comparison as the control signal Set.

The comparator 124 compares the voltage of the node N 0 with the reference voltage Vreset, and outputs a signal based on the result of the comparison as the control signal Reset.

The flip-flop circuit 14 sets data based on the control signal Set, and resets data based on the control signal Reset. Specifically, the flip-flop circuit 14 sets data “1” based on the control signal Set, and resets data “0” based on the control signal Reset. According to data of the flip-flop circuit 14, the switch SW is set to an on/off (conductive/non-conductive) state.

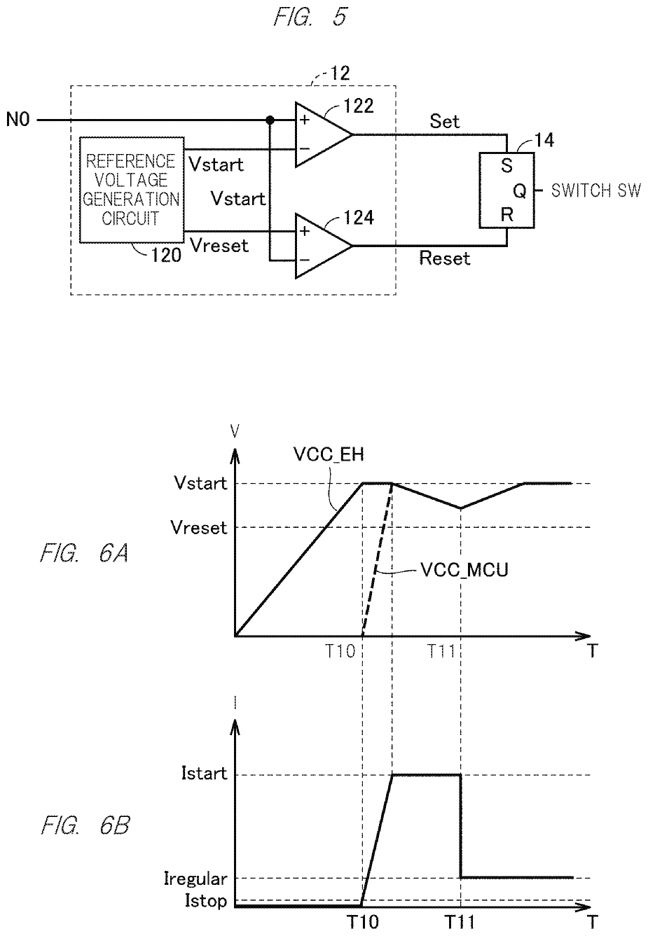

FIGS. 6A and 6B are diagrams for explaining an operation example of the solar system 1 according to the first embodiment. As shown in FIG. 6A, when the voltage reaches the reference voltage Vstart at the time T10, the start-up sequence operation of the microcomputer 20 is started.

In this case, the voltage detection circuit 12 sets data of the flip-flop circuit 14. Accordingly, the switch SW is turned on. After the switch SW is turned on, the current ICC flows out.

Therefore, as shown in FIG. 6A, a voltage VCC_EH of the node N0 starts to decrease. The voltage VCC_MCU of the internal node N1 rises based on the conduction of the switch SW. The voltage VCC_EH of the node N0 and The voltage VCC_MCU of the internal node N1 become the same voltage level. On the other hand, the capacitor 15 is coupled to the node N0. The capacitor 15 is charged by the solar cell 2. The electric charge charged in the capacitor 15 is discharged and thus the voltage VCC_EH gradually drops.

In this case, there is shown a case that the start-up sequence operation is completed at time T11 and the microcomputer 20 shifts to the low power mode.

As shown in FIG. 6B, in the low power mode, the current ICC is maintained at a current Iregular.

The switch SW of the control device 5 according to the first embodiment is turned on when the voltage VCC_EH of the node N0 reaches the reference voltage Vstart.

Therefore, the solar cell 2 is not coupled to the load which is the microcomputer 20 because the switch SW is turned off until the switch SW is turned on. Therefore, it is possible to avoid the problem that the start-up sequence operation cannot be executed because the load of the microcomputer 20 is heavy and the voltage level is low at the initial stage of power-on.

The node N0 is coupled to the capacitor 15. Therefore, the capacitor 15 is charged until the voltage VCC_EH of the node N0 reaches the reference voltage Vstart.

Therefore, even when the switch SW is turned on and the voltage VCC_EH is lowered, the charge charged in the capacitor 15 is discharged, thereby making it possible to reduce speed of the lowering of the voltage VCC_EH. That is, it is possible to suppress a sharp voltage drop.

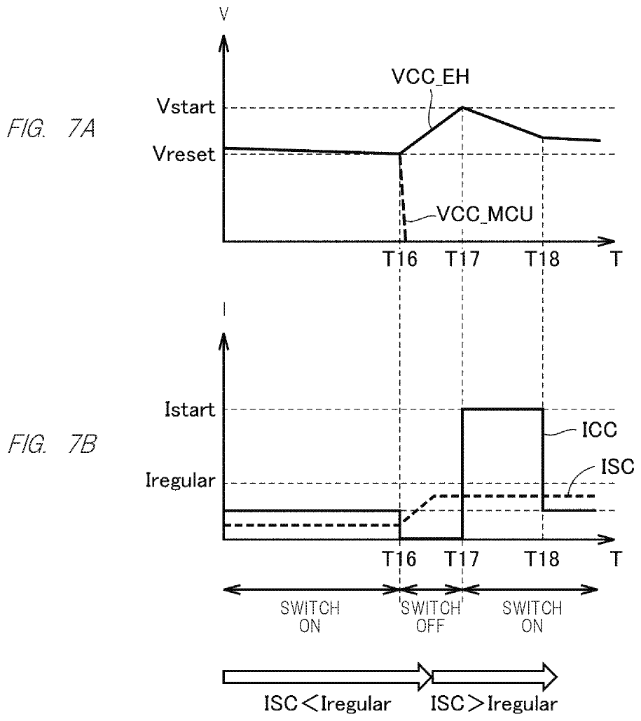

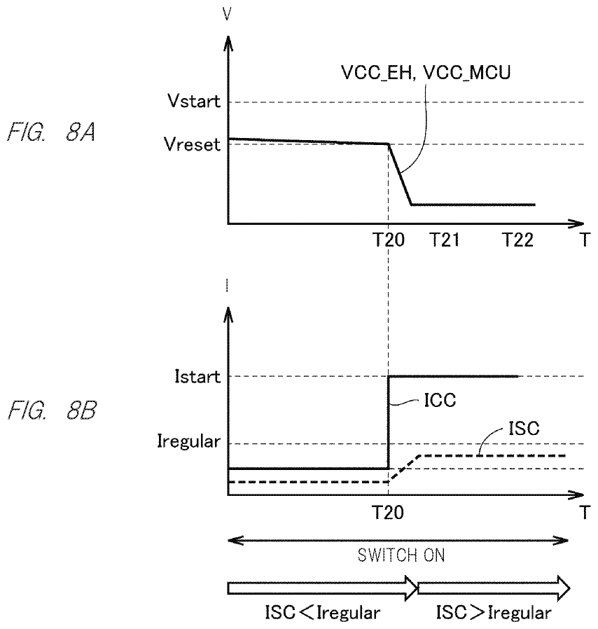

Therefore, it is possible to surely complete the start-up sequence operation. FIGS. 7A and 7B diagrams for explaining an operation example of the solar system 1 based on the first embodiment.

In this case, there is shown a case that a power generation capability of the solar cell 2 is temporarily lowered to be lower than the current Iregular.

FIG. 7A shows a case in which the voltage VCC_MCU of the internal node N1 and the voltage VCC_EH of the node N0 decrease to the reference voltage Vreset that the microcomputer 20 is reset, even in a steady-state at time T16. Accordingly, the voltage detection circuit 12 outputs the control signal Reset. The flip-flop circuit 14 resets data based on the control signal Reset. Therefore, the switch SW is turned off. As a result, the power consumption is reduced, so that the voltage VCC_EH of the node N0 rises when the solar cell 2 recovers.

The voltage VCC_EH can then be restored to the reference voltage Vstart. At time T17, when the voltage VCC_EH reaches the reference voltage Vstart, the switch SW is turned on. Then, the microcomputer 20 executes the start-up sequence operation.

It is possible to operate the microcomputer 20 continuously. FIGS. 8A and 8B are the other diagram for explaining an operation example of the solar system 1# as the comparison example.

As shown in FIG. 8, there is shown a case that the voltage VCC_EH of the node N0 decrease at the time T20. The voltage detection circuit 12# outputs the control signal Reset. Accordingly, a restart operation of the microcomputer 20 is executed.

The current ICC increases to a current Istart according to the restart operation of the microcomputer 20. Even when the solar cell 2 recovers at this time and a power generation current ISC from the solar cell 2 exceeds the current Iregular, the voltage VCC_MCU decreases unless the power generation current ISC exceeds the current Istart.

Therefore, the voltage cannot be recovered, and the voltage for completing the start-up sequence operation cannot be secured.

Therefore, according to the configuration in which the switch SW of the control device 5 according to the first embodiment are provided, the start-up sequencing operation can be restarted stably even when the power generation capacity of the solar cell 2 is temporarily lowered and the power generation capacity is less than the current Iregular.

### Second Embodiment

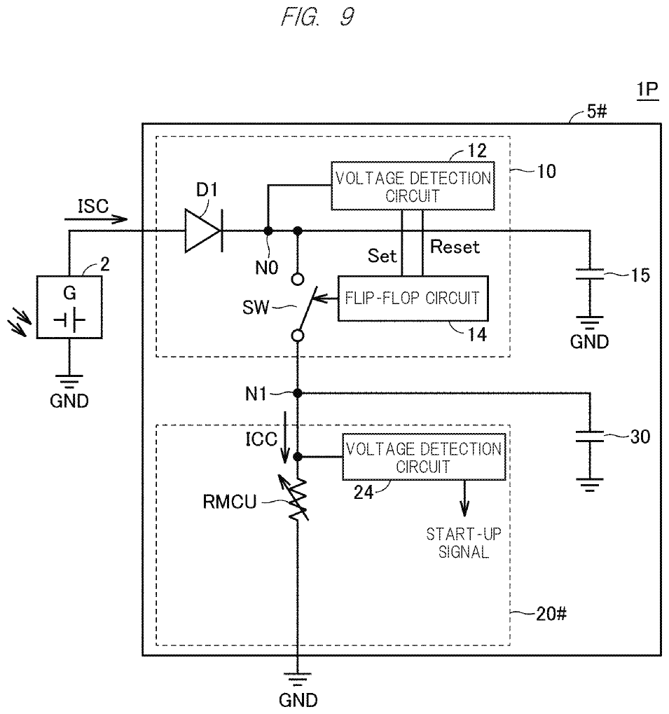

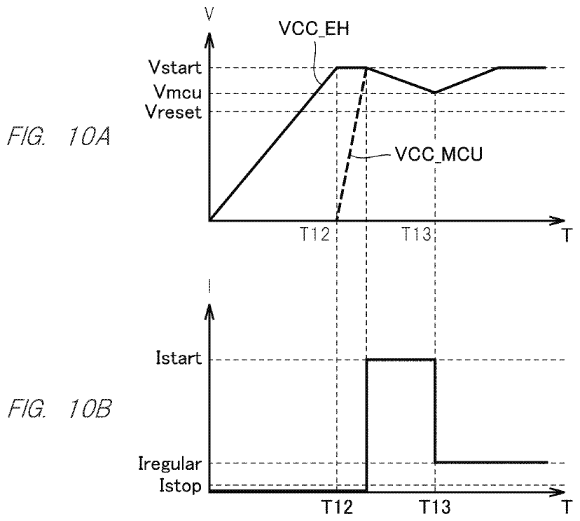

FIG. 9 is a diagram for explaining an outline of a solar system 1P according to a second embodiment.

Referring to FIG. 9, the solar system 1P differs from the solar system 1 in that the microcomputer 20 is replaced with a microcomputer 20# and a capacitor 30 coupled to internal node N1 is provided in parallel with the microcomputer 20#. Since other configurations are the same, detailed description thereof will not be repeated. In this case, a configuration in which the capacitor 30 is provided will be described, but the present invention is not limited to the capacitor, and a secondary battery may be used. In addition, the configuration is not limited to the configuration built in a control device 5#, and the configuration may be such that the capacitor 30 is coupled at an outside of the control device 5#.

The microcomputer 20# further includes a voltage detection circuit 24 as compared with the microcomputer 20. The voltage detection circuit 24 detects the voltage level of the internal node N1, and outputs a start-up signal based on the detection result. Specifically, the voltage detection circuit 24 determines whether or not the voltage level of the internal node N1 is equal to or greater than a voltage Vmcu. The voltage detection circuit 24 outputs the start-up signal when it is judged that the voltage level of the internal node N1 is equal to or greater than the voltage Vmcu.

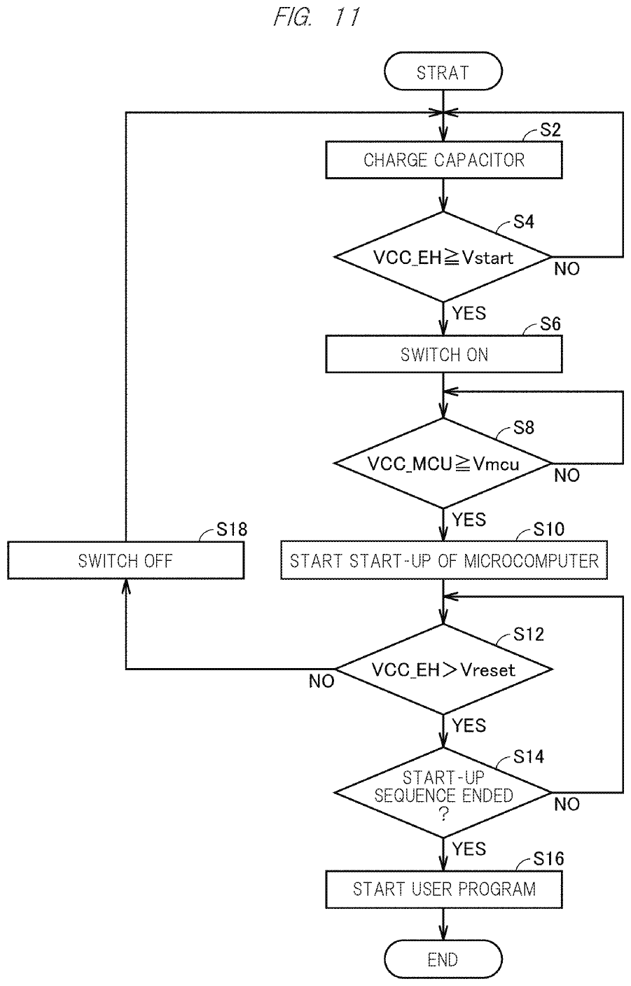

The microcomputer 20# is activated based on the start-up signal to execute a start-up sequence operation. FIGS. 10A and 10B are diagrams for explaining an operation example of the solar system 1P according to the second embodiment.

As shown in FIG. 10A, the voltage VCC_EH reaches the reference voltage Vstart at time T12. In this case, the voltage detection circuit 12 sets data of the flip-flop circuit 14. Accordingly, the switch SW is turned on.

Then, the voltage VCC_MCU of the internal node N1 rises. The capacitor 30 is coupled to the internal node N1. The capacitor 30 is charged by the solar cell 2. The voltages of the node N0 and the internal node N1 become the same voltage level.

The voltage detection circuit 24 outputs the start-up signal when the voltage VCC_MCU of the internal node N1 becomes equal to or higher than the voltage Vmcu.

Accordingly, the microcomputer 20# is activated based on the start-up signal to execute the start-up sequence operation.

Since the configuration according to the first embodiment does not have the start-up signal for the microcomputer 20, and the microcomputer 20 is started by rising of the voltage VCC_MCU, there is a possibility that the start-up sequence operation of the microcomputer 20 is started and the microcomputer 20 becomes unstable when the voltage VCC_MCU is low. On the other hand, in the configuration according to the second embodiment, the start-up sequence operation is started when the voltage VCC_MCU is equal to or higher than the voltage Vmcu. Therefore, it is possible to stably start the startup sequence operation.

As shown in FIG. 10B, there is shown a case that the current ICC flows out when the voltage VCC_MCU of the inner node N1 becomes equal to or higher than the voltage Vmcu.

As shown in FIG. 10A, when the current ICC flows out, the voltage VCC_EH of the node N0 starts to decrease. On the other hand, the capacitor 15 is coupled to the node N0. The capacitor 30 is coupled to the node N0 via the switch SW. The capacitors 15 and 30 are charged by the solar cell 2. In the voltage VCC_EH, the charges charged in the capacitors 15 and 30 are discharged and the voltage level gradually drops.

In this case, there is shown a case that the start-up sequence operation is completed at time T13 and the microcomputer 20# shifts to the low power mode.

As shown in FIG. 10B, in the low power mode, the current ICC is maintained at the current Iregular.

The switch SW of the control device 5# according to the second embodiment is turned on when the voltage VCC_EH of the node N0 reaches the reference voltage Vstart.

Therefore, the solar cell 2 is not coupled to the load which is the microcomputer 20 because the switch SW is turned off until the switch SW is turned on. Therefore, it is possible to avoid the problem that the start-up sequence operation cannot be executed because the load of the microcomputer 20# is heavy and the voltage level is low at the initial stage when the power is turned on.

When the voltage of the internal node N1 becomes equal to or higher than the voltage Vmcu, the microcomputer 20# is activated. The internal node N1 is coupled to the capacitor 30. Therefore, the capacitor 30 is charged until the voltage VCC_MCU of the inner node N1 reaches the voltage Vmcu.

Therefore, even when the microcomputer 20# is activated by the start-up signal and the voltage VCC_EH is lowered, the charge charged in the capacitors 15 and 30 is discharged, thereby making it possible to reduce the speed of the lowering of the voltage VCC_EH. That is, it is possible to suppress a sharp voltage drop. Therefore, it is possible to more reliably complete the start-up sequence operation.

FIG. 11 is a flow chart for explaining an operation of the solar system 1P according to the second embodiment.

Referring to FIG. 11, in step S2, the capacitor 15 is charged. As a result, the voltage level of the node N0 rises.

In step S4, the voltage detection circuit 12 detects whether the voltage VCC_EH of the node N0 has reached the reference voltage Vstart.

In step S4, when the voltage VCC_EH of the node N0 does not reach the reference voltage Vstart, the voltage detection circuit 12 returns to step S2 and repeats the above process.

Meanwhile, in step S4, when it is determined that the voltage VCC_EH of node N0 has reached the reference voltage Vstart, the voltage detection circuit 12 sets the flip-flop circuit 14. In step S6, the switch SW is turned on.

In step S8, the detection circuit 24 detects whether the voltage VCC_MCU of the internal node N1 is equal to or higher than the voltage Vmcu.

In step S8, the voltage detection circuit 24 maintains the state of step S8 if it does not detect that the voltage VCC_MCU of the internal node N1 is equal to or greater than the voltage Vmcu.

Meanwhile, in step S8, when it is determined that the voltage VCC_MCU of the internal node N1 is equal to or more than the voltage Vmcu, the voltage detection circuit 24 outputs the start-up signal and starts the start sequence operation of the microcomputer 20# (step S10).

In step S12, the voltage detection circuit 12 detects whether the voltage VCC_EH of the node N0 is higher than the reference voltage Vreset.

In step S12, when the voltage VCC_EH of the node N0 is larger than the reference voltage Vreset, the voltage detection circuit 12 proceeds to step S14.

In step S14, the microcomputer 20# determines whether the start-up sequence operation is completed.

In step S14, when it is determined that the start-up sequence operation is not completed (“N0” in step S14), the microcomputer 20# returns to step S12 and repeats the above process.

Meanwhile, in step S14, when it is determined that the start-up sequence operation has been completed (“YES” in step S14), the microcomputer 20# starts the user program (step S16). It is possible to transition to the low power mode by the user program.

Then, the process ends. In step S12, when the voltage detection circuit 12 detects that the voltage VCC_EH of the node N0 is not larger than the reference voltage Vreset, that is, smaller than the voltage VCC_EH of the node N0 (“N0” in step S 12), the voltage detection circuit 12 proceeds to step S18.

The voltage detection circuit 12 resets the flip-flop circuit 14 when it is determined that the voltage VCC_EH of the node N0 is less than the reference voltage Vreset. In step S18, the switch SW is turned off. Then, the process returns to step S2. Third embodiment

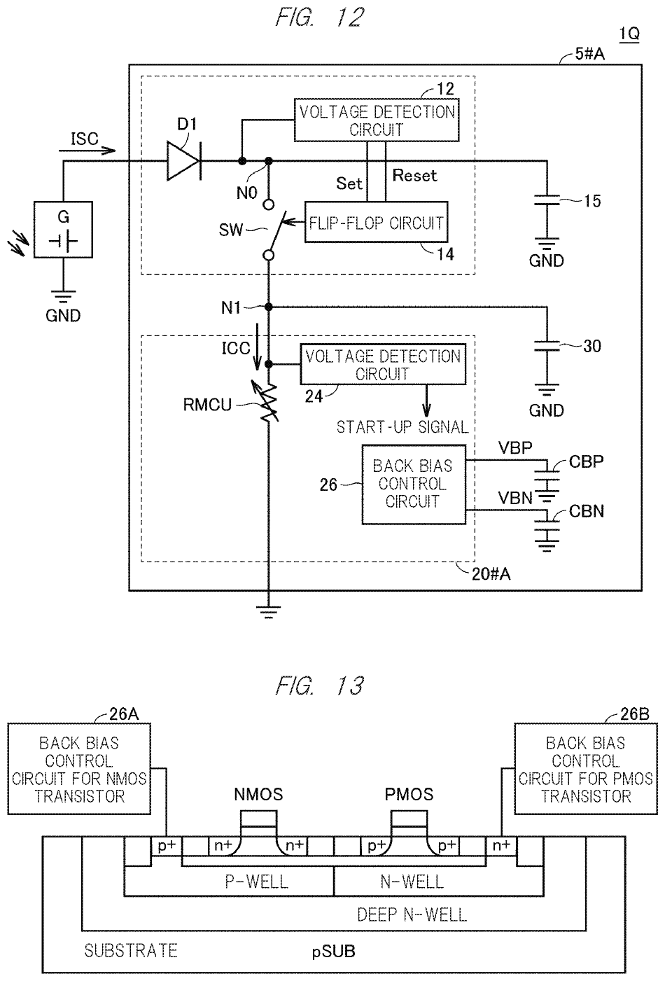

FIG. 12 is a diagram for explaining an outline of a solar system 1Q according to a third embodiment.

Referring to FIG. 12, the solar system 1Q replaces the microcomputer 20 with a microcomputer 20#A as compared with the solar system 1P.

The microcomputer 20#A further includes a back bias control circuit 26 and capacitors CBP and CBN. In this case, a configuration in which the capacitors CBP and CBN are provided will be described, but the present invention is not particularly limited to this configuration, and a parasitic capacitance of a well may be used. In addition, the configuration is not limited to the configuration built in a control device 5#A, and a configuration may be such that the capacitors CBP and CBNs are coupled at an outside of the control device 5#A.

The back bias control circuit 26 controls back biases of MOS transistors. FIG. 13 is a diagram for explaining a configuration of a MOSFET formed on an SOI (Silicon on Insulator) wafer.

Referring to FIG. 13, the MOEFET formed on the SOI wafer can suppress a leakage current when the MOS transistor is turned off, by changing back bias voltages of wells of NMOS and PMOS transistors.

The back bias control circuit 26 includes a back bias control circuit 26A for the PMOS transistor and a back bias control circuit 26B for the NMOS transistor.

A deep n-well is formed in a substrate pSUB, and a p-well and a n-well are formed therein. The back bias control circuits 26A and 26B for the PMOS and NMOS transistors generate back bias voltages VBP and VBN of the PMOS and NMOS transistors from the power supply voltage, and supply the back bias voltages VBP and VBN to the n-well and the p-well, respectively.

Here, if the bias variation VBB is assumed, the back bias voltage VBP of the PMOS transistor is set to “the power supply voltage+the bias variation VBB”, and the back bias voltage VBN of the NMOS transistor is set to “a ground voltage GND—the bias variation VBB”. That is, the back bias voltage VSUB of the NMOS transistor becomes a negative voltage.

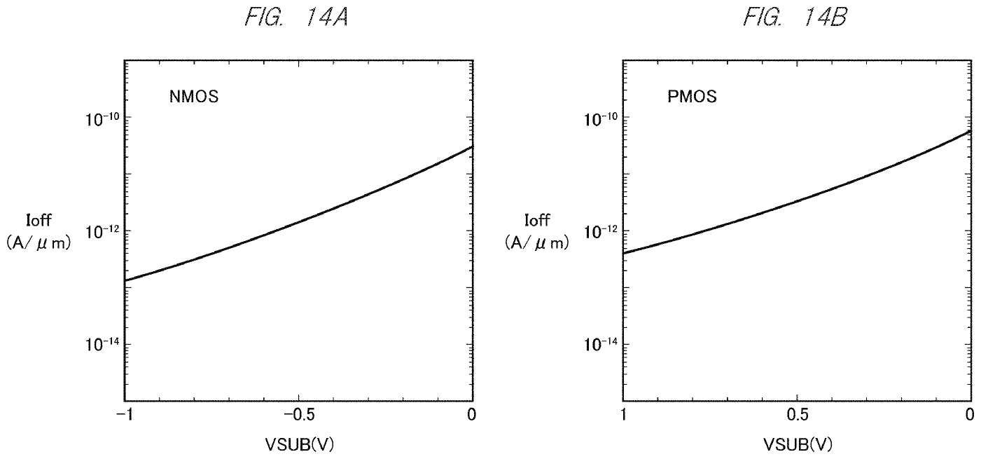

FIGS. 14A and 14B are diagrams for explaining a relation between the back bias voltage VSUB and a leakage current Ioff in an off state of the MOS transistor.

As shown in FIG. 14, in the MOS transistor, the dominant factor of the leakage current is a subthreshold leakage current.

In the NMOS transistor, the leakage current can be reduced by making the back-bias voltage negative. In the case of the PMOS transistor, the leakage current can be reduced by making it positive.

Here, the leakage current changes exponentially with respect to a change in the back bias voltage. Therefore, the amount of change in the leakage current is large when the back bias voltage is around 0V, and the amount of change in the leakage current is small when the back bias voltage is increased.

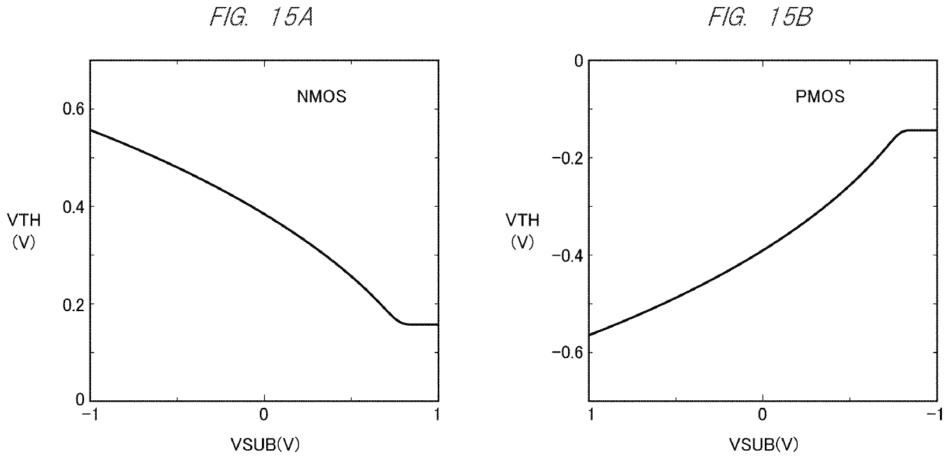

FIGS. 15A and 15B are diagrams for explaining a relation between a threshold voltage and the back bias voltage. As shown in FIG. 15, in the case of the NMOS transistor, an absolute value of the threshold voltage is increased by making the back bias voltage negative, and in the case of the PMOS transistor, the absolute value of the threshold voltage is increased by making the back bias voltage positive.

Since the leakage current can be reduced in the state in which the back bias voltage is applied, the consumption current of the circuit in the standby state can be reduced. On the other hand, since a threshold voltage VTH of the MOS transistor becomes high, it is necessary to lower a clock frequency of a circuit for generating a clock, for example.

In the state in which the back bias voltage is released, the consumption current of the circuit in the standby state increases. On the other hand, the clock frequency of the circuit for generating the clock can be increased.

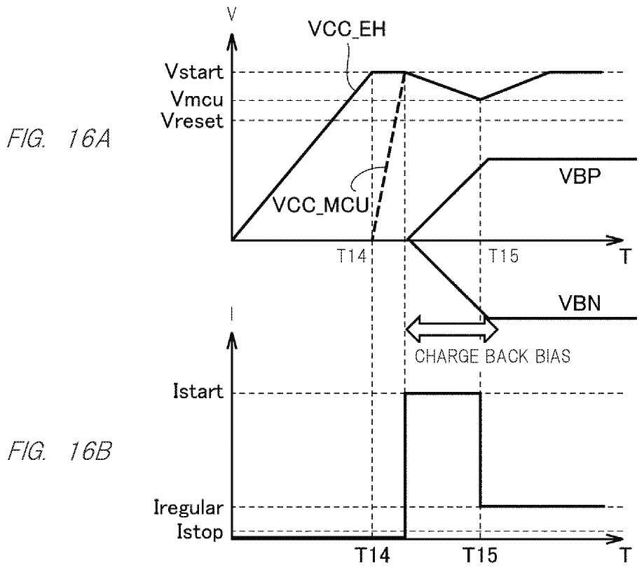

FIG. 16A and 16B are diagrams for explaining an operation example of the solar system 1Q according to the third embodiment. As shown in FIG. 16A, the voltage VCC_EH reaches the reference voltage Vstart at time T14. In this case, the voltage detection circuit 12 sets data of the flip-flop circuit 14. Accordingly, the switch SW is turned on.

Then, the voltage VCC_MCU of the internal node N1 rises. The capacitor 30 is coupled to the internal node N1. The capacitor 30 is charged by the solar cell 2. The voltages of the node N0 and the internal node N1 become the same voltage level.

The voltage detection circuit 24 outputs the start-up signal when the voltage VCC_MCU of the internal node N1 becomes equal to or higher than the voltage Vmcu.

Accordingly, the microcomputer 20# is activated based on the start-up signal to execute the start-up sequence operation. When the voltage VCC_MCU of the internal node N1 of the microcomputer 20#A is 0 V, the back bias control circuit 26 does not operate. Therefore, the back bias voltages VBP and VBN are 0 V. That is, the state is the back bias release state. At this time, the microcomputer 20#A consumes a large amount of power.

The microcomputer 20#A starts the start-up sequence operation, and the back bias control circuit 26 operates based on the start-up signal. As a result, the back bias control circuit 26 charges the capacitors CBP and CBN. The back bias voltages VBP and VBN are raised to the voltage of the back bias application state.

Even when the current Istart during this period exceeds the power generation current ISC of the solar cell 2, the shortage can be compensated by the charges charged in the capacitors 15 and 30.

When the start-up sequence operation is completed and the back bias voltages VBP and VBN become the voltages in the back bias application state, the microcomputer 20#A shifts to the low power mode.

If the steady-state current Iregular of the microcomputer 20#A at this time is smaller than the power generation current ISC, thereafter, the current consumed by the microcomputer 20#A can be supported by the power generation capability of the solar cell 2 without depending on the charges of the capacitor. The microcomputer 20#A can be operated continuously regardless of the capacitance of the capacitor.

Although the present disclosure has been specifically described based on the embodiments described above, the present disclosure is not limited to the embodiments, and it is needless to say that various modifications can be made without departing from the gist thereof.

What is claimed is:

1. A semiconductor device driven by a power supply voltage generated by a power generation device, the semiconductor device comprising:
a load circuit receiving the power supply voltage;
a switch provided between the power generation device and the load circuit;
a first capacitor connected to the power generation device in parallel with the switch; and
a switch control circuit controlling the first switch based on a voltage level of a power supply node disposed between the power generation device and the first capacitor.

2. The semiconductor device according to claim 1,
wherein the switch control circuit sets the switch conductive when the voltage level of the power supply node reaches a voltage level of a first reference voltage, and sets the switch non-conductive when the voltage level of the power supply node is equal to or less than a voltage level of a second reference voltage.

3. The semiconductor device according to claim 2,
wherein the switch control circuit includes a comparison circuit for comparing the voltage level of the power supply node with the voltage levels of the first and second reference voltages, and a flip-flop circuit for controlling the switch based on the comparison result of the comparison circuit.

4. The semiconductor device according to claim 3,
wherein the comparison circuit includes a first comparator for comparing the voltage level of the power supply node with the voltage level of the first reference voltage, and a second comparator for comparing the voltage level of the power supply node with the voltage level of the second reference voltage, and the flip-flop circuit for setting the switch to be conductive based on the comparison result of the first comparator and for setting the switch to be non-conductive based on the comparison result of the second comparator.

5. A semiconductor device driven by a power supply voltage generated by a power generation device, the semiconductor device comprising:
a load circuit receiving the power supply voltage from a power supply node;
a switch provided between the power supply node and the load circuit;
a first capacitor connected to the power supply node in parallel with the switch; and
a switch control circuit controlling the first switch based on a voltage level of the power supply node.

6. The semiconductor device according to claim 5,
wherein the switch control circuit sets the switch conductive when the voltage level of the power supply node reaches a voltage level of a first reference voltage, and sets the switch non-conductive when the voltage level of the power supply node is equal to or less than a voltage level of a second reference voltage.

7. The semiconductor device according to claim 6,
wherein the switch control circuit includes a comparison circuit for comparing the voltage level of the power supply node with the voltage levels of the first and second reference voltages, and a flip-flop circuit for controlling the switch based on the comparison result of the comparison circuit.

8. The semiconductor device according to claim 7,
wherein the comparison circuit includes a first comparator for comparing the voltage level of the power supply node with the voltage level of the first reference voltage, and a second comparator for comparing the voltage level of the power supply node with the voltage level of the second reference voltage, and the flip-flop circuit for setting the switch to be conductive based on the comparison result of the first comparator and for setting the switch to be non-conductive based on the comparison result of the second comparator.

9. The semiconductor device according to claim 8,
wherein the comparison circuit further includes a reference voltage generation circuit for generating the first and second reference voltages.

10. The semiconductor device according to claim 5,
wherein the switch control circuit outputs a reset signal for resetting the load circuit based on the voltage level of the power supply node.

11. The semiconductor device according to claim 5, further comprising a second capacitor coupled to an internal node between the switch and the load circuit.

12. The semiconductor device according to claim 11, further comprising a voltage detection circuit for detecting a voltage level of the internal node and outputting a start-up signal for starting the load circuit based on the detection result.

13. The semiconductor device according to claim 12,
wherein the load circuit is formed of a MOS transistor and includes a back bias control circuit for controlling a back bias voltage of the MOS transistor.

14. The semiconductor device according to claim 13,
wherein the back bias control circuit sets the threshold voltage of the MOS transistor high based on the start-up signal.

15. The semiconductor device according to claim 5,
wherein a power consumption of the load circuit at the time of start-up is larger than a power consumption of the load circuit at the time of steady state.

16. The semiconductor device according to claim 15,
wherein the power consumption of the load circuit at the time of steady state is smaller than a power generation amount generated by the power generation device.
